(19) United States
(12) Patent Application Publication
(10) Pub. No.: US 2015/0048962 A1
(43) Pub. Date: Feb. 19, 2015

(54) ELECTROMAGNETIC ANECHOIC CHAMBER AND UNIFORM FIELD AREA TESTING APPARATUS

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: TEN-CHEN HO, New Taipei (TW); XIAO-LIAN HE, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/010,548

(22) Filed: Aug. 27, 2013

(30) Foreign Application Priority Data
Aug. 19, 2013 (CN) 2013103614369

(51) Int. Cl. G01R 1/067; H01Q 17/00

(52) U.S. Cl. CPC G01R 1/06705; H01Q 17/00
USPC 342/1; 324/750.22

(57) ABSTRACT

An electromagnetic anechoic chamber includes a chamber, an antenna mounted therein at a first end, a test bench mounted therein at a second end, and a uniform field area (UFA) testing apparatus. The UFA testing apparatus includes a supporting bar horizontally mounted, a sliding member on the supporting bar, a first driving mechanism to move the sliding member, an upright toothed rack movably supported by the sliding member, a second driving mechanism rotating a gear on the supporting bar to lift or drop the upright rack, and a field intensity probe mounted to a bottom end of the rack. The first driving mechanism and the second driving mechanism can position the field intensity probe at any planar point inside the chamber to avoid any manual repositioning of the field intensity probe during testing.

### BACKGROUND

1. Technical Field

The present disclosure relates to electromagnetic anechoic chamber, and particularly to an electromagnetic anechoic chamber with an uniform field area testing apparatus.

2.Description of Related Art

Before electromagnetic compatibility (EMC) test, the field area in which the test is to be implemented should be verified first, to ensure accuracy of the measurements of electromagnetic strength. The field area with uniform electromagnetic strength is usually called a uniform field area (UFA). Typically, the size of the UFA is a plane area of 1.5 m*1.5 m (wherein m stands for meters), and includes 16 test points equally spaced on the UFA. The distance between every two neighboring test points is 0.5 m. When testing a UFA, a field strength probe is placed on one of the test points, and a signal generator, a power amplifier, and an antenna transmit signals with different frequencies and different polarities for the test. The field strength probe receives the signals at a point, and measures the field strength at that point. After measuring the field strength at a test point, the field strength probe should be moved to another test point, and each step of the abovementioned test is repeated. Finally, collecting the field strength of all the test points, and evaluating the uniformity of field strength must be done. However, manually adjusting the antenna polarity for the field strength probe at each point of test is inconvenient and easily leads to an inaccurate test result.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of an electromagnetic anechoic chamber, wherein the electromagnetic anechoic chamber includes a uniform field area (UFA) testing apparatus.

FIG. 2 is an enlarged isometric view of the UFA testing apparatus of FIG. 1.

FIG. 3 is an enlarged view of the circled portion III of FIG. 2.

FIG. 4 is an assembled, isometric view of the electromagnetic anechoic chamber of FIG. 1.

FIG. 5 is front side plan view of the electromagnetic anechoic chamber of FIG. 4.

FIG. 6 is similar to FIG. 5, but showing a different state of use.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean “at least one.”

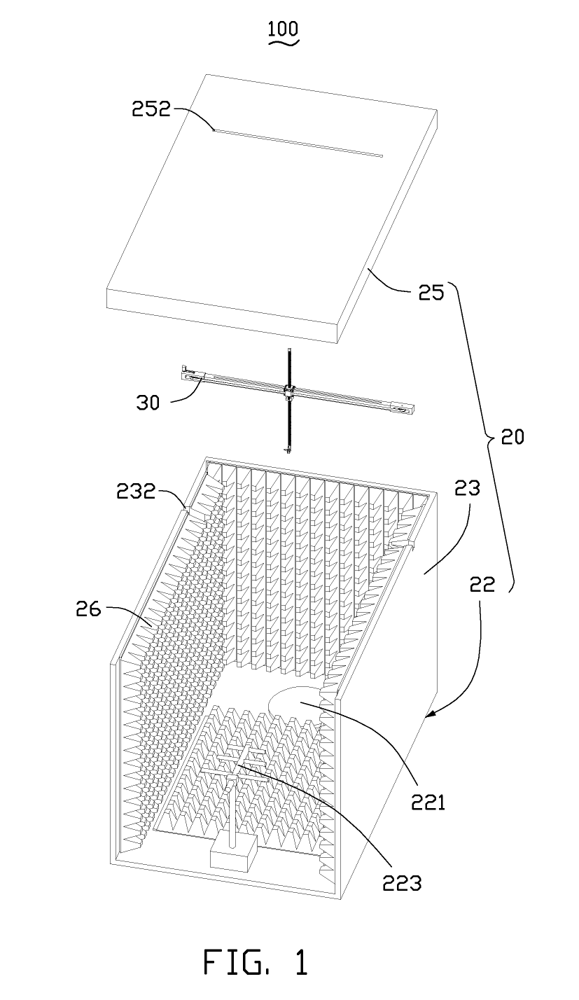

FIG. 1 shows an exemplary embodiment of an electromagnetic anechoic chamber 100 including a chamber 20 and a uniform field area (UFA) testing apparatus 30.

The chamber 20 includes a rectangular bottom wall 22, a sidewall 23 perpendicularly extending up from sides of the bottom wall 22, and a cover 25. Electromagnetic wave absorptive material 26 is spread on inner surfaces of the bottom wall 22, the sidewall 23, and the cover 25. A test bench 221 is mounted on a first end of the bottom wall 22, and an antenna 223 is mounted on a second end of the bottom wall 22 opposite to the test bench 221. A top of the sidewall 23 defines two opposite cutouts 232 adjacent to the test bench 221. An end of the cover 25 defines a guiding slot 252 extending through top and bottom of the cover 25.

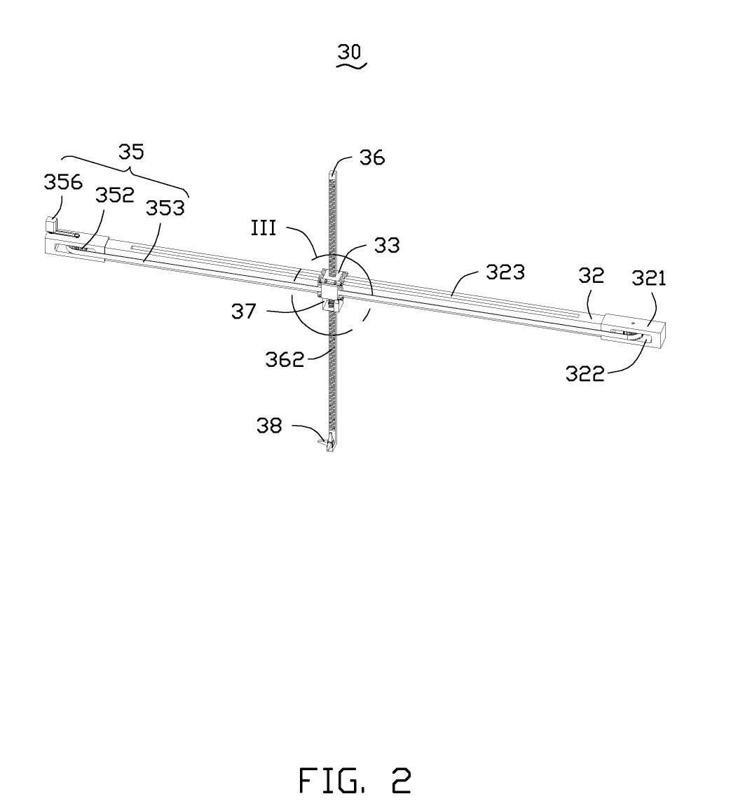

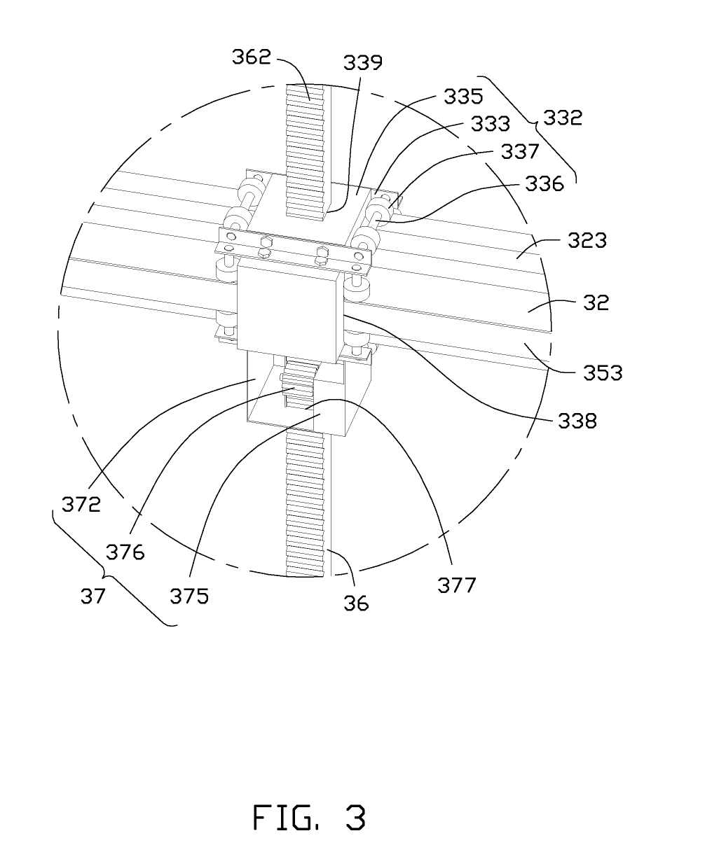

FIGS. 2-3 show the UFA testing apparatus 30 including a supporting bar 32, a sliding member 33 slidably fitting about the supporting bar 32, a first driving mechanism 35, a rack 36, a second driving mechanism 37, and a field intensity probe 38.

Two opposite mounting portions 321 extend out from ends of the supporting bar 32. Each mounting portion 321 defines a through hole 322 extending through front and rear surfaces of the mounting portion 321. The supporting bar 32 defines a slide slot 323 extending through top and bottom surfaces of the supporting bar 32, and the slide slot 323 extends lengthwise along the supporting bar 32.

The sliding member 33 includes a sliding shell 332 slidably fitted about the supporting bar 32. In the embodiment, the sliding shell 332 includes four sliding plates 335 connected end to end through four angle irons 333, two shafts 336 connected between every two adjacent angle irons 333 and located at opposite ends of the sliding plate 335, and two conveying wheels 337 pivotably fitted about each shaft 336. The sliding plate 335 positioned at the front of the supporting bar 32 defines a mounting hole 338 extending lengthwise along the supporting bar 32. Two opposite sliding plates 335 positioning at the top and bottom of the supporting bar 32 define two opposite guiding holes 339 aligning with the slide slot 323 of the supporting bar 32.

The first driving mechanism 35 includes two adjusting wheels 352 rotatably mounted in the through holes 322 of the supporting bar 32, an endless transmission belt 353 around the adjusting wheels 352, and a first motor 356 mounted to one of the mounting portions 321. The transmission belt 353 extends through and is mounted in the mounting hole 338 of the sliding plate 335. The first motor 356 drives the adjusting wheels 352 to rotate, the rotation of the adjusting wheels 352 drives the transmission belt 32 to move lengthwise along the supporting bar 32, and the transmission belt 353 pulls the sliding shell 332 along the supporting bar 32.

The rack 36 includes a plurality of splines or teeth (teeth 362) formed on a front surface of the rack 36 and arranged crosswise along the length of the rack 36. The rack 36 is slidably received in the guiding holes 339 of the sliding plates 335 and the slide slot 323 of the supporting bar 32. The field intensity probe 38 is mounted on a bottom end of the rack 36.

The second driving mechanism 37 includes an installing shell 372 mounted to a bottom of the sliding shell 332 and a second motor 375 installed in the installing shell 372. The second motor 375 includes a gear wheel 376. The installing shell 372 defines a though hole 377 aligning with the guiding holes 339 of the sliding shell 332. The rack 36 can be slidably received in the through hole 377, and the teeth 362 of the rack 36 engage with the gear wheel 376.

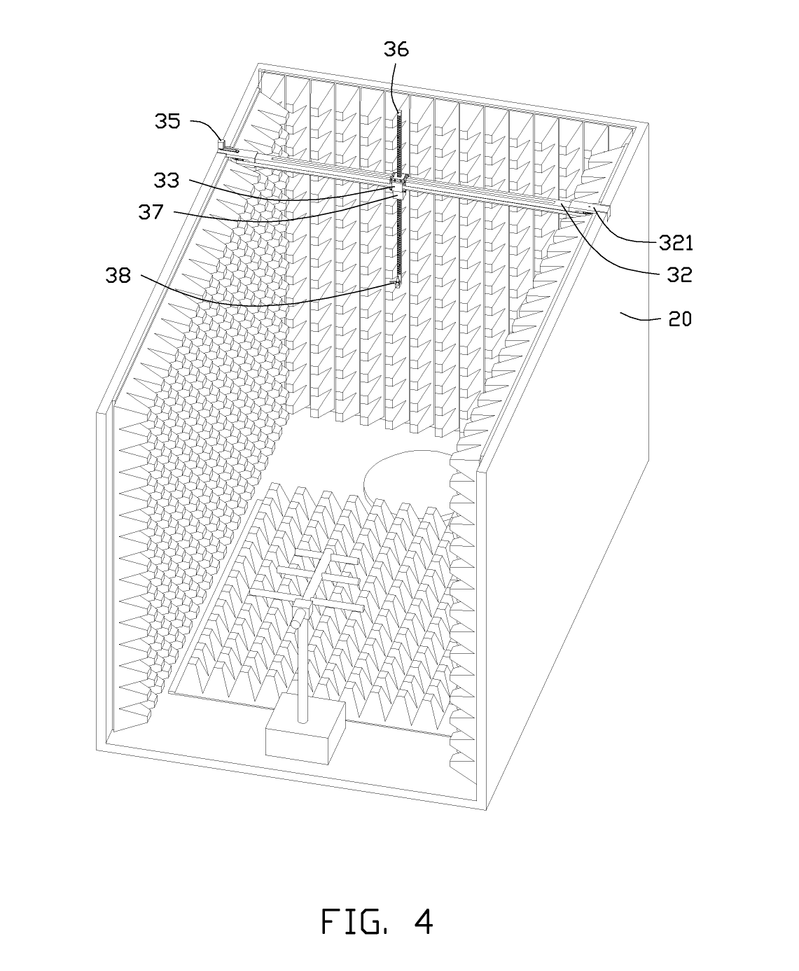

FIG. 4 shows that in assembly of the electromagnetic anechoic chamber 100, the mounting portions 321 are latched in the cutouts 232 of the chamber 20, and the field intensity probe 38 faces the antenna 223. The cover 25 is on the top of the sidewall 23, and the upper portion of the rack 36 is slidably received in the guiding slot 252 of the cover 25.

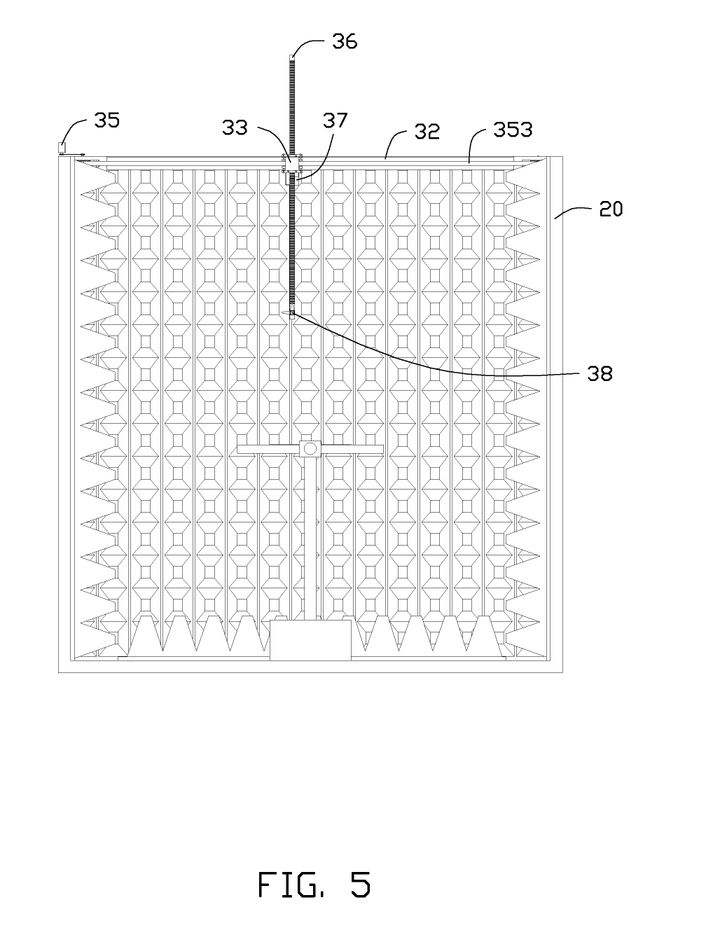

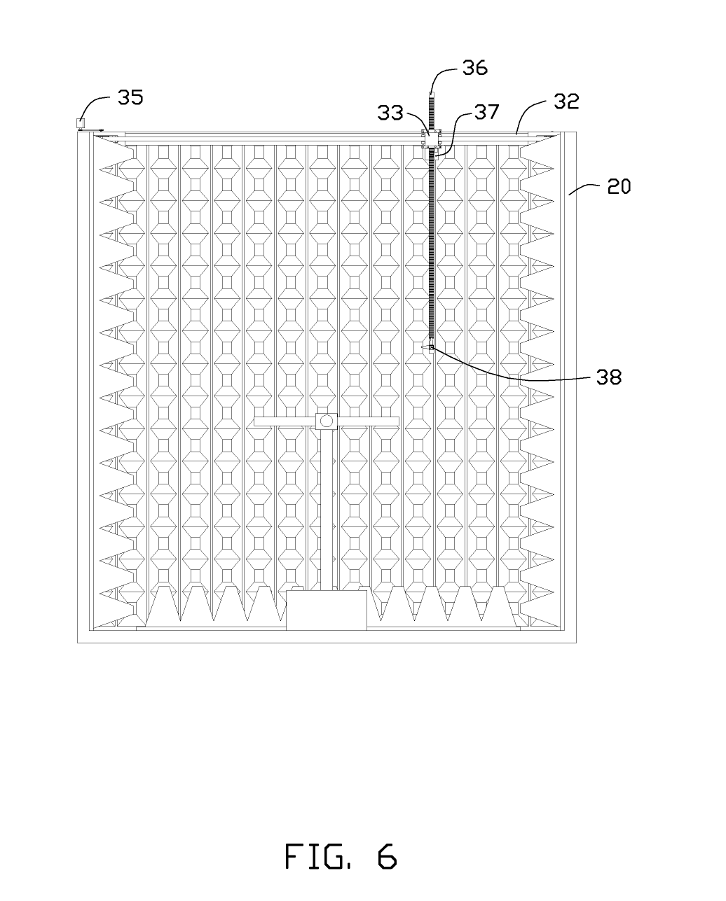

FIGS. 5-6 shows the operation of the electromagnetic anechoic chamber 100. The first motor 356 operates to rotate the adjusting wheels 352, the adjusting wheels 352 drive the transmission belt 32 to move, and the transmission belt pulls the sliding shell 332 along the supporting bar 32. The second motor 375 operates to rotate the gear wheel 376, and the gear wheel 376 drives the rack 36 to move along a direction perpendicular to the supporting bar 32. Thus, the field intensity probe 38 can be moved to each test point of the UFA test of the electromagnetic anechoic chamber 100.

Even though numerous characteristics and advantages of the embodiments have been set forth in the foregoing description, together with details of the structure and function of the embodiments, the present disclosure is illustrative only, and changes may be made in detail, especially in the matters of shape, size, and arrangement of parts within the principles of the embodiments to the full extent indicated by the broad general meaning of the terms in which the appended claims are expressed.

What is claimed is:

1. A uniform field area (UFA) testing apparatus, comprising:
a supporting bar;
a sliding member slidably fitted about the supporting bar;
a first driving mechanism driving the sliding member to slide along the supporting bar;
a rack slidably installed to the sliding member along a direction perpendicular to the supporting bar;
a second driving mechanism driving the rack to slide relative to the sliding member; and
a field intensity probe mounted to a bottom end of the rack.

2. The UFA testing apparatus of claim 1, wherein the supporting bar defines a slide slot extending through two opposite side surfaces of the supporting bar, the rack is slidably received in the slide slot of the supporting bar.

3. The UFA testing apparatus of claim 2, wherein the sliding member comprises a sliding shell slidably fitted about the supporting bar, the sliding shell defines two opposite guiding holes aligning with the slide slot of the supporting bar, the rack is slidably received in the guiding holes of the sliding shell.

4. The UFA testing apparatus of claim 3, wherein the sliding shell comprises four sliding plates connected end to end through four angle irons, the guiding holes are defined two opposite sliding plates positioning at top and bottom of the supporting bar.

5. The UFA testing apparatus of claim 4, wherein the sliding shell further comprises two shafts connected between every two adjacent angle irons and located at two opposite ends of the corresponding sliding plate, two conveying wheels are pivotably fitted about each shaft.

6. The UFA testing apparatus of claim 4, wherein the first driving mechanism comprises two adjusting wheels rotatably installed to two opposite ends of the supporting bar, a transmission belt coiled on the adjusting wheels, and a first motor driving the adjusting wheels to rotate, the transmission belt is mounted to the sliding shell.

7. The UFA testing apparatus of claim 7, wherein one of the sliding plates defines a mounting hole, the the transmission belt is mounted in the mounting hole.

8. The UFA testing apparatus of claim 3, wherein the second driving mechanism comprises an installing shell mounted to a bottom of the sliding shell and a second motor installed in the installing shell, the second motor comprises a gear wheel, the rack extends through the installing shell, and the rack is engaged with the gear wheel.

9. An electromagnetic anechoic chamber, comprising:
a chamber;
an antenna mounted at a first end of the chamber;
a test bench mounted at a second end of the chamber opposite to the antenna; and
a uniform field area testing apparatus comprising:
a supporting bar horizontally mounted on a top of the chamber;
a sliding member slidably fitted about the supporting bar;
a first driving mechanism driving the sliding member to slide along the supporting bar;
a rack slidably installed to the sliding member along an upright direction;
a second driving mechanism driving the rack to slide; and
a field intensity probe mounted to a bottom end of the rack opposite to the antenna.

10. The electromagnetic anechoic chamber of claim 9, wherein the supporting bar defines a slide slot extending through top and bottom surfaces of the supporting bar, the rack is slidably received in the slide slot of the supporting bar.

11. The electromagnetic anechoic chamber of claim 10, wherein the sliding member comprises a sliding shell slidably fitted about the supporting bar, the sliding shell defines two opposite guiding holes aligning with the slide slot of the supporting bar, the rack is slidably received in the guiding holes of the sliding shell.

12. The electromagnetic anechoic chamber of claim 11, wherein the first driving mechanism comprises two adjusting wheels rotatably installed to two opposite ends of the supporting bar, a transmission belt coiled on the adjusting wheels, and a first motor driving the adjusting wheels to rotate, the transmission belt is mounted to the sliding shell.

13. The electromagnetic anechoic chamber of claim 11, wherein the second driving mechanism comprises an installing shell mounted to a bottom of the sliding shell and a second motor installed in the installing shell, the second motor comprises a gear wheel, the rack extends through the installing shell, and the rack is engaged with the gear wheel.
